(19) United States
(12) Patent Application Publication
(10) Pub. No.: US 2021/0391227 A1
(43) Pub. Date: Dec. 16, 2021

(54) SUPPORT SUBSTRATE FOR INTEGRATED CIRCUIT, ELECTRONIC DEVICE, AND CORRESPONDING PRODUCTION AND PACKAGING METHODS

(71) Applicant: STMicroelectronics (Grenoble 2) SAS, Grenoble (FR)

(72) Inventors: Richard REMBERT, Quaix en Chartreuse (FR); Didier SIGNORET, Grenoble (FR); Olivier FRANIATTE, Grenoble (FR)

(73) Assignee: STMicroelectronics (Grenoble 2) SAS, Grenoble (FR)

(21) Appl. No.: 17/345,600

(22) Filed: Jun. 11, 2021

(30) Foreign Application Priority Data
Jun. 15, 2020 (FR) 2006208

(51) Int. Cl. H01L 23/13; H01L 23/31; H01L 23/498; H01L 23/00; H01L 21/48; H01L 21/56

(52) U.S. Cl. CPC H01L 23/13; H01L 23/3121; H01L 23/49838; H01L 24/32; H01L 24/48; H01L 2924/35121; H01L 21/4853; H01L 21/565; H01L 2224/32238; H01L 2224/48227; H01L 2224/73265; H01L 24/73

(57) ABSTRACT

An electronic device includes a support substrate. A face is covered with a soldermask layer. At least part of the soldermask layer includes roughnesses providing a rough grip surface. An electronic die is mounted on the support substrate. A molding resin encapsulates the electronic die and partially or completely covers the soldermask layer.

### PRIORITY CLAIM

This application claims the priority benefit of French Application for Patent No. 2006208, filed on Jun. 15, 2020, the content of which is hereby incorporated by reference in its entirety to the maximum extent allowable by law.

### TECHNICAL FIELD

Embodiments and implementations relate to electronic devices incorporating an integrated circuit and the packaging of electronic devices and, in particular, relate to the support substrates for integrated circuits.

### BACKGROUND

At the end of the production line, quality problems can appear when packaging electronic devices.

Indeed, during packaging, an integrated circuit (referred to as a die) is assembled on a support substrate, and an encapsulation element is added to protect the die, so as to form an electronic device ready for use and capable of being handled without special precautions.

The support substrate is conventionally covered with a layer of resin varnish, called a soldermask, in order to insulate and protect interconnection metal tracks of the support substrate.

The encapsulation element comprises, for example, a molding resin covering the soldermask layer so as to embed the elements mounted on the support substrate.

However, delaminations, that is to say detachments or separations, have been observed at the interface between the die fixing adhesive and the support substrate and also at the interface between the molding resin and the support substrate.

It is possible that a delamination of the molding resin propagates and leads to delamination of the die fixing adhesive, and conversely it is possible that a delamination of the die fixing adhesive causes delamination of the molding resin.

These delaminations result in defective products that are removed from the production and distribution line. Alternatively, these delaminations may appear later, in a product sold, or even worse when using a finished product equipped with the electronic device. A faulty electronic device can cause major malfunction of the finished product.

Conventional solutions for priming the support substrate by exposure to chemical plasma have the disadvantages of having a non-homogeneous effect on the surface of the support substrate, of heating to high temperatures which may be incompatible with some substrates, and of using expensive investment and maintenance equipment.

There is a need in the art to address the foregoing and other issues.

### SUMMARY

According to one aspect, provision is made of a support substrate for an integrated circuit, including a face covered with a soldermask layer, wherein at least part of the soldermask layer includes roughnesses forming a rough grip surface.

Indeed, the typically very smooth texture of the soldermask layer of the conventional structures does not promote the securing of the fixing of adhesives or the molding resins with the support substrate.

However, the support substrate according to this aspect advantageously comprises a soldermask morphologically modified so as to have roughnesses, that is to say sharp irregularities in shape. The rough grip surface formed by said roughnesses is thus provided to promote the securing of elements intended to be bonded on the surface of the support substrate, such as an electronic die, and a molding resin encapsulating the die and covering the support substrate.

The solution according to this aspect has the advantages of being reliable, perfectly controllable (in particular in terms of homogeneity of the gripping surface), without particular constraints (in particular in terms of temperature), and very economical.

According to one embodiment, said roughnesses comprise plastic deformations of the soldermask layer.

According to one embodiment, said roughnesses comprise protruding elements of an additional soldermask layer, deposited on the soldermask layer.

According to another aspect, provision is made of an electronic device including a support substrate as defined above, an electronic die mounted on the support substrate, and a molding resin encapsulating the electronic die and covering the soldermask layer.

According to one embodiment, the molding resin covers said at least part of the soldermask layer including roughnesses forming a rough grip surface.

According to one embodiment, the electronic die is bonded on said at least part of the soldermask layer including roughnesses forming a rough grip surface.

According to another aspect, provision is made of a method for producing a support substrate for an integrated circuit, comprising forming a soldermask layer covering a face of a support substrate body, and forming roughnesses forming a rough grip surface on at least part of the soldermask layer.

According to one implementation, said formation of roughnesses comprises a plastic deformation of the soldermask layer.

According to one implementation, said formation of roughnesses comprises forming protruding elements in an additional soldermask layer, deposited on said soldermask layer.

According to another aspect, provision is made of a method for packaging an electronic device, comprising producing a support substrate according to a method as defined above, mounting an electronic die on the support substrate, and molding a molding resin encapsulating (i.e., encapsulating) the electronic die and covering the soldermask layer.

According to one implementation, the molding of the molding resin covers said at least part of the soldermask layer including roughnesses forming a rough grip surface.

According to one implementation, mounting the electronic die comprises bonding the die on said at least part of the soldermask layer including roughnesses forming a rough grip surface.

### BRIEF DESCRIPTION OF THE DRAWINGS

Other advantages and features of the invention will become apparent upon examining the detailed description of embodiments and implementations, which are in no way limiting, and of the appended drawings, wherein:

FIG. 1 illustrates a support substrate for an integrated circuit;

FIG. 2A illustrates a step of forming roughnesses to provide a rough grip surface over an entire extent of a soldermask layer;

FIG. 2B illustrates roughnesses resulting from the plastic deformation described in relation to FIG. 2A;

FIG. 3A illustrates another example of a step of forming roughnesses to provide a rough grip surface over an entire extent of a soldermask layer;

FIG. 3B illustrates roughnesses resulting from the plastic deformation described in relation to FIG. 3A;

FIG. 4 illustrates the result of a step of bonding an electronic die on the soldermask layer;

FIG. 5 illustrates the result of a step of molding a molding resin encapsulating the electronic die and partially or completely covering the soldermask layer;

FIG. 6 illustrates the result of a step of forming roughnesses on the soldermask layer;

FIG. 7 shows a top view of the support substrate described in relation to FIG. 6;

FIG. 8 illustrates the result of a step of bonding the electronic die 400 to the soldermask layer and of a step of injecting a molding resin; and

FIG. 9 illustrates another example of an electronic device including a support substrate covered with a soldermask layer and a molding resin 500 encapsulating an electronic die and at least partially covering the soldermask layer.

### DETAILED DESCRIPTION

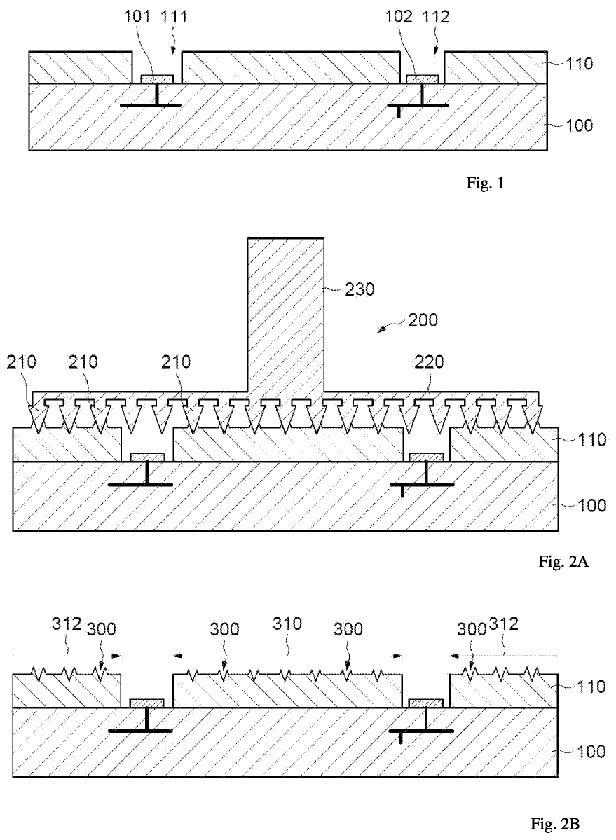

FIG. 1 illustrates a support substrate for an integrated circuit, for example in the context of a packaging of the “Ball Grid Array” (BGA) package type or of the plane (or land) contact “Land Grid Array” (LGA) package type.

The support substrate includes conductive contact sockets 101, 102 on a mounting face, connected to an interconnection network located in the support substrate body 100. In the context of BGA packages, the ball grid (not shown) is provided on the face opposite the mounting face.

The support substrate body 100 typically comprises a stack (not shown) of metal levels separated by insulating layers and connected by vias, to form the interconnection network.

The support substrate body 100 is further covered by a soldermask layer 110 to protect and insulate metal tracks extending over the mounting face.

The soldermask layer 110 is formed so as to have openings 111, 112 giving access to the conductive contact sockets 101, 102.

The formation of the soldermask layer 110 is typically obtained by a damascene-type method. This method comprises depositing a fluid or dry resin (in the form of a solid film) in the openings of a temporary “negative” mask. The resin is then crosslinked (solidified), typically by photo-reaction to UV (ultra-violet) irradiation, and the temporary mask is then removed.

The soldermask layer 110 can be about ten micrometers thick, or more.

FIG. 2A illustrates a step of forming roughnesses 300 (see, FIG. 2B) providing a rough grip surface over the entire extent of the soldermask layer 110 upper surface.

An abrasive tool 200 is used to form the roughnesses 300 in the soldermask layer 110.

The abrasive tool 200 includes a field of sharp elements 210 distributed over a plate 220. The plate 220 is secured to an arm 230 allowing for the manipulation of the tool 200, for example with an automatic machine for component disposition (such as, for example, a “pick and place” machine).

The tips of the sharp elements 210 are brought close to the surface of the soldermask layer 110, and pressure is applied perpendicularly to the soldermask layer 110, in order to produce a plastic deformation of the soldermask layer 110 at its supper surface.

The soldermask 110, which in provided at this step in the solid state (or at least in a state of high viscosity), nevertheless has some ductility.

The pressure force transmitted by the sharp elements 210 in the soldermask layer 110 is thus selected so as to produce an irreversible plastic (or viscoplastic) deformation of the soldermask 210.

The deformation thus produced can, for example, be comparable to a stamping of the sharp elements 210 into the upper surface of the soldermask layer 110.

Optionally, a lateral back and forth movement (that is to say parallel to the soldermask layer 110) of the abrasive tool, such as with a scratching, can be provided.

Reference is made to FIG. 2B.

FIG. 2B illustrates the roughnesses 300 which result from the plastic deformation described in relation to FIG. 2A.

The roughnesses 300 have a shape that is substantially complementary to the shape of the tips 210 of the tool 200, and comprise a depressed part of hollow shape whose bottom has an acute angle.

The roughnesses 300 may further comprise burrs on the edges of the depressed parts. The burrs protrude from the upper surface of the soldermask layer 110 at an acute angle.

The depressed part and the burrs of the roughnesses 300 both contribute in the appearance of irregularities, allowing the rough grip surface to be formed.

The soldermask layer 110 may have a thickness of substantially 10 μm (micrometer). The vertical pressure of the tool 200 is applied at a force established with respect to the ductility of the soldermask to form roughnesses 300 having a depth, for example, comprised between 2 μm and 5 μm.

The spacing between two neighboring roughnesses can be selected at the finest dimension of what is possible to construct the tool 200, in particular the spacing between two sharp elements 210 on the plate 220. For example, this spacing may comprise between 50 μm and 250 μm, even more.

In the example of FIGS. 2A and 2B, the rough grip surface 310, 312 is shaped by the tool 200 over the entire extent of the soldermask layer 110.

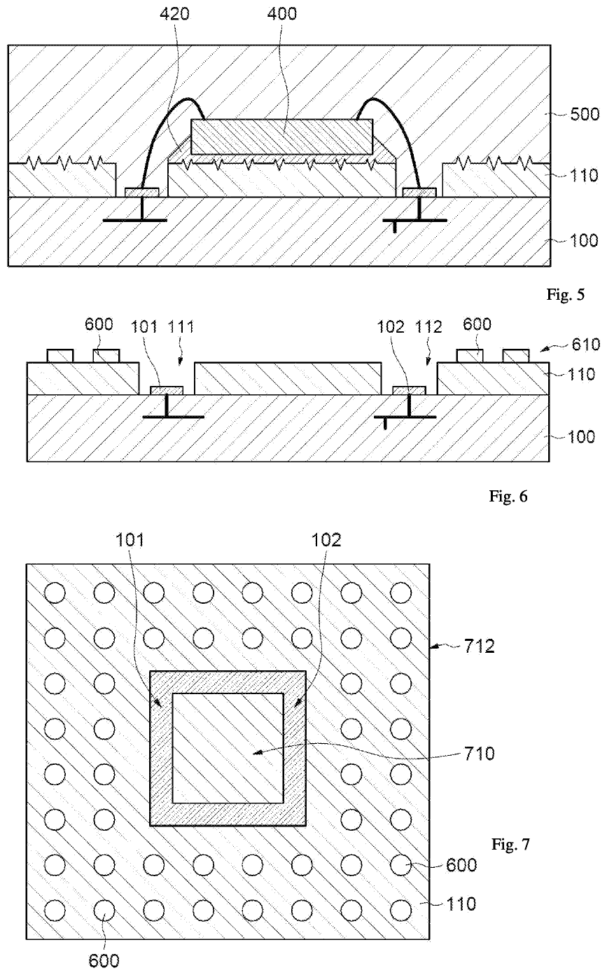

In particular, the rough grip surface is formed on a part 310 of the soldermask layer 110 intended to accommodate an electronic die 400 (FIG. 4), and on a part 312 of the soldermask layer 110 intended to be in the contact with a molding resin 500 (FIG. 5).

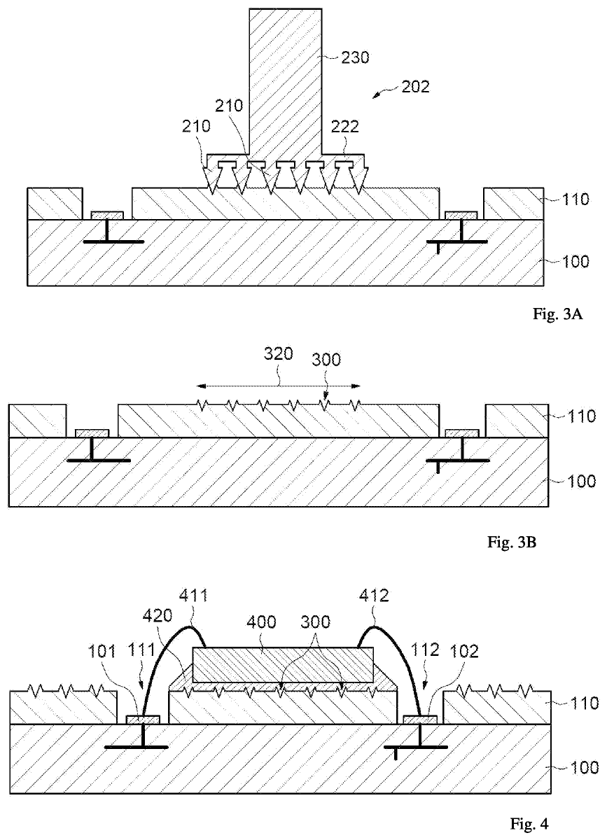

FIG. 3A illustrates another example of the step of forming roughnesses 300, to form a rough grip surface on a localized region of upper surface of the soldermask layer 110.

In this example, the abrasive tool 202 is of the same composition as the tool 200 described in relation to FIG. 2A, but the plate 222 supporting the sharp elements 210 is of smaller dimension, so as to cover only the region located between the openings 111, 112 giving access to the contact sockets 101, 102, of the soldermask layer 110.

FIG. 3B illustrates the roughnesses 300 which result from the plastic deformation produced by the abrasive tool 202 described in relation to FIG. 3A. The roughnesses 300 naturally have the same shape as described in relation to FIG. 2B.

In this example, the rough grip surface formed on the soldermask layer 110 is located at a region 320 intended to accommodate an electronic die 400 (FIG. 4) and in particular a die fixing adhesive 420 (FIG. 4).

Thus, a support substrate 100 for an integrated circuit including a face covered with a soldermask layer 110 is obtained where a least part 310, 312 of the soldermask layer 110 includes roughnesses 300 that form a rough grip surface. Two examples of an implementation of a method for producing such a support substrate are illustrated.

The rough grip surface of the soldermask allows and supports the making of a strong securing of the elements that will be bonded to the support substrate, such as will occur during a method for packaging an electronic device.

The term “electronic device” as used herein means an integrated circuit (electronic die) mounted on the support substrate and covered by an encapsulation element such as a molding resin, that is to say the result of the packaging steps.

Reference is made in this regard to FIGS. 4 and 5.

FIG. 4 illustrates the result of a step of bonding an electronic die 400 on the soldermask layer 110, in particular on the rough grip surface 310, 320 obtained as described in relation to FIGS. 2A-2B, or 3A-3B.

A layer of adhesive 420 is deposited on the region of soldermask 110 located between the openings 111, 112, the upper surface of which comprises the roughnesses 300, and the die 400 is disposed on the adhesive 420.

The adhesive 420 will thus conform to the shape of the roughnesses 300 of the gripping surface 310, and form anchoring points on vertical and horizontal discontinuous surfaces. This results in a bond that is more resistant to delamination than conventional bonds wherein the adhesive is placed on a smooth surface of the soldermask.

The die 400 is connected with the interconnection network of the support substrate body 100 in a conventional manner by connecting wires 411, 412 extending between solder pads located on the upper face of the die (that is to say the face opposite to the bonded face, on the last level of the interconnection part of the die, usually “BEOL” according to the term well known to the person skilled in the art) and the contact sockets 101, 102 in the openings 111, 112.

FIG. 5 illustrates the result of a step of molding a molding resin 500 encapsulating the electronic die 400 and partially or completely covering the soldermask layer 110.

The molding conventionally comprises disposing the structure shown in FIG. 4 within a mold defining a hollow chamber accommodating at the very least the volume occupied by the die 400, the connecting wires 411, 412, and extending beyond the openings 111, 112 of the soldermask.

The molding resin 500 is then injected into the chamber, so as to embed all the elements therein. The die 400 is thus encapsulated in molding resin 500 and the soldermask layer 110 is at least partially covered by the molding resin 500.

The molding resin 500 has a bonding power and becomes integral with the support substrate on the soldermask layer, during drying (or crosslinking).

In the example of FIG. 2B, the rough grip surface is formed over region 312 to be covered by the molding resin.

Thus, the molding resin 500 conforms to the shape of the roughnesses 300 of the gripping surface 312, forming anchor points on discontinuous vertical and horizontal surfaces. This results in an interface between the molding resin 500 and the support substrate more resistant to delamination than the conventionally smooth interfaces.

FIGS. 6 and 7 illustrate another exemplary implementation of a method for producing the support substrate for an integrated circuit, including a face covered with a soldermask layer 110 having at least one part including roughnesses 600 forming a rough grip surface.

FIG. 6 illustrates the result of a step of forming roughnesses 600 on the soldermask layer 110. In this example, a support substrate 100 is covered with a first soldermask layer 110 as described above in relation to FIG. 1.

The first soldermask layer 110 naturally includes the openings 111, 112 which allow the contact sockets 101, 102 of the substrate 100 to be connected.

An additional soldermask layer 610 is formed on the first layer of cross-linked soldermask 110, and uses a second temporary mask, the pattern of which provides for a multitude of point openings distributed over the surface.

The second temporary mask can, of course, provide for covering the positions of the openings 111, 112 so as not to plug them, or alternatively, the formation of the additional layer 610 can reuse the temporary mask used for the first soldermask layer 110, so as not to plug the openings 111, 112.

The additional soldermask 610 is then crosslinked, and the temporary mask is then removed. A multitude of protruding elements 600 are thus formed in the additional soldermask layer 610 above the first soldermask layer.

The additional soldermask layer 610 can also have a thickness of approximately 10 μm (micrometer), and the spacing between two neighboring protruding elements 600 can be selected at the finest dimension of what is allowed by the method for forming the additional layer 610.

For example, the protruding elements may have a cylindrical shape with a diameter comprised between 50 μm and 250 μm, and the spacing between two neighboring protruding elements 600 may be of the same order of magnitude.

It will be noted that the section of the protruding elements 600 (that is to say the outline of the projecting elements 600 formed on the soldermask layer 110) is not necessarily circular, and may have any shape permitted by the second temporary mask, such as squares, rectangles, stars, etc.

The protruding elements 600 as a whole thus form a castellated surface, comprising hollow parts between two protruding elements 600, at the first soldermask layer 110, vertical sides, and prominent parts at the additional soldermask layer 610.

The hollow parts, the sides of the protruding elements and the prominent parts form roughnesses 600 allow for the formation of irregularities in appearance, in particular vertical and horizontal discontinuities of the surface.

The roughnesses 600 thus defined by the protruding elements form a rough grip surface for the soldermask layer 110.

FIG. 7 shows a top view of the support substrate described in relation to FIG. 6.

In this representation, an internal part 710 is defined, framed by a connection area comprising the contact sockets 101, 102, and an external part 712 of the soldermask layer 110 at the periphery of the connection area.

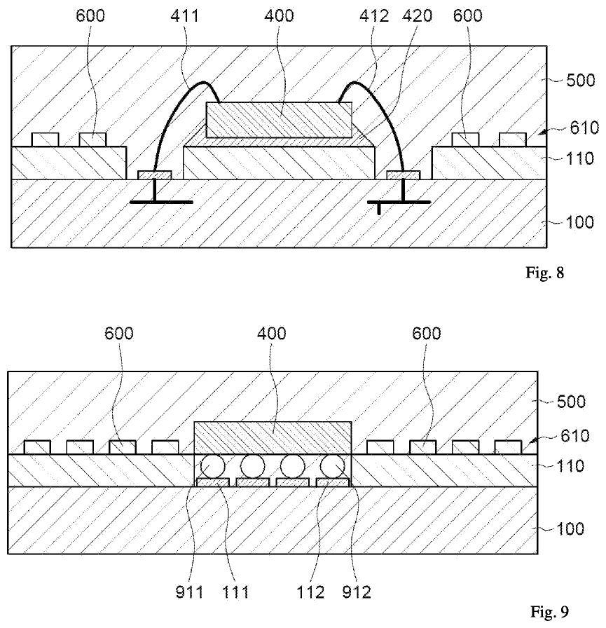

In this example, the roughnesses 600 were formed only on the outer part 712, intended to be covered by the molding resin 500 (FIG. 8).

The internal part 710 of the soldermask layer 110 is intended to accommodate the bonding of an electronic die 400 (FIG. 8), and, in this example, does not include roughness 600.

This example is advantageous, for example, in the context of constraints imposed on the conditions for bonding the die, which may be incompatible with the presence of the projecting elements 600 on this part 710.

However, protruding elements 600 of the additional soldermask layer 610 can also be provided on the internal part 710, to benefit from the advantages of the rough grip surface for bonding the die 400, if the constraints of the bonding allow it.

FIG. 8 illustrates the result of a step of bonding the electronic die 400 to the soldermask layer 110 and the result of a step of injecting a molding resin 500. These steps are carried out in a manner similar to the steps described previously in relation with FIGS. 4 and 5, the common elements of which bear the same references in FIG. 8 and will not be detailed again here.

The die 400 is thus encapsulated by the molding resin 500, and the rough grip surface of the outer part 712 of soldermask 110 is covered by the molding resin 500.

The molding resin 500 conforms to the castellated shape of the roughnesses 600 of the gripping surface 712, forming anchor points on vertical and horizontal discontinuous surfaces. This results in an interface between the molding resin 500 and the support substrate more resistant to delamination than conventional interfaces.

FIG. 9 illustrates, similarly to the electronic devices described in relation to FIGS. 5 and 8, another example of an electronic device including a support substrate 100 covered with a soldermask layer 110. An electronic die 400 is mounted on the support substrate 100, within an opening formed in the soldermask layer 110, and a molding resin 500 encapsulates the electronic die 450 and at least partially covers the soldermask layer 110.

In this example, the electronic die 400 is not coupled with the interconnection network of the support substrate body 100 by connecting wires, but instead by solder balls or pads (“pillar”) on the last level of the interconnection part of the “BEOL” die. This corresponds to the technique called “flip chip”.

The solder balls or pads 911, 912 are welded or bonded by conductive adhesive points, on the contact sockets 111, 112, within the opening of the soldermask layer 110, and the die is thus not bonded, strictly speaking, on the soldermask layer 110, but rather is bonded to the support body 100.

This being the case, the part 712 (FIG. 7) of the soldermask layer 110 covered by the molding resin 500, has a rough grip surface, allowing a strong securing of the resin 500 to the substrate 100, therefore not very subject to delamination.

Moreover, the invention herein is not limited to the embodiments and implementations but encompasses all the variants thereof, for example, the support substrates described in relation to FIGS. 1 to 5 can accommodate the mounting of a flip chip, and the rough grip surfaces could of course be formed on parts of the soldermask layer which have not been exemplified here, while benefiting from the advantages of the invention.

1. An electronic device, comprising:
a support substrate including a face;
a soldermask layer covering said face, wherein an upper surface of the soldermask layer includes roughnesses providing a rough grip surface;
an electronic die bonded to said roughnesses at a first part of the rough grip surface for said soldermask layer; and
a molding resin encapsulating the electronic die and covering the soldermask layer.

2. The electronic device according to claim 1, wherein the molding resin is bonded to said roughnesses at a second part of the rough grip surface for said soldermask layer.

3. The electronic device according to claim 2, wherein said roughnesses comprise plastic deformations of the soldermask layer forming said rough grip surface.

4. The electronic device according to claim 2, wherein said roughnesses comprise protruding elements formed by an additional soldermask layer which covers said soldermask layer only at said second part of the rough grip surface.

5. The electronic device according to claim 4, wherein portions of an upper surface of said soldermask layer are present between protruding elements of said additional soldermask layer.

6. The electronic device according to claim 1, wherein the face of the support substrate includes conductive contact sockets provided in openings extending through the soldermask layer, and further comprising connecting wires passing through said openings which electrically connect the electronic die to the conductive contact sockets.

7. An electronic device, comprising:
a support substrate including a face, wherein the face of the support substrate includes conductive contact sockets;
a soldermask layer covering said face, wherein an upper surface of the soldermask layer includes roughnesses providing a rough grip surface, said soldermask layer including an opening extending through the soldermask layer to expose said conductive contact sockets;
an electronic die mounted in said opening of the soldermask layer and electrically connected to the conductive contact sockets; and
a molding resin encapsulating the electronic die and bonded to said roughnesses for the rough grip surface of the soldermask layer.

8. The electronic device according to claim 7, wherein said roughnesses comprise plastic deformations of the soldermask layer forming said rough grip surface.

9. The electronic device according to claim 8, wherein said roughnesses comprise protruding elements formed by an additional soldermask layer which covers said soldermask layer.

10. The electronic device according to claim 9, wherein portions of an upper surface of said soldermask layer are present between protruding elements of said additional soldermask layer.

11. A method for packaging an electronic device, comprising:
applying a soldermask layer to cover a face of a support substrate body;
forming roughnesses in an upper surface of the soldermask layer to produce a rough grip surface on the upper surface of the soldermask layer;
bonding an electronic die to said roughnesses at a first part of the rough grip surface for said soldermask layer; and
molding a molding resin to encapsulate the electronic die and cover the soldermask layer.

12. The method of claim 11, wherein forming roughnesses comprises applying plastic deformations to the upper surface of the soldermask layer.

13. The method of claim 11, wherein forming roughnesses comprises applying an additional soldermask layer which covers said soldermask layer only at a second part of the rough grip surface.

14. The method of claim 13, wherein applying comprises shaping said additional soldermask layer such that portions of the upper surface of said soldermask layer are present between protruding elements of said additional soldermask layer.

15. The method of claim 13, wherein molding the molding resin comprises bonding to said second part of the rough grip surface.

16. A method for packaging an electronic device, comprising:
applying a soldermask layer to cover a face of a support substrate body, wherein the face of the support substrate includes conductive contact sockets;
forming an opening extending through said soldermask layer to expose said conductive contact sockets;
forming roughnesses in an upper surface of the soldermask layer to produce a rough grip surface on the upper surface of the soldermask layer;
installing an electronic die in said opening and electrically connecting said electronic die to said conductive contact sockets; and
molding a molding resin to encapsulate the electronic die and cover the soldermask layer.

17. The method of claim 16, wherein forming roughnesses comprises applying plastic deformations to the upper surface of the soldermask layer.

18. The method of claim 16, wherein forming roughnesses comprises applying an additional soldermask layer which covers said soldermask layer only at a second part of the rough grip surface.

19. The method of claim 18, wherein applying comprises shaping said additional soldermask layer such that portions of the upper surface of said soldermask layer are present between protruding elements of said additional soldermask layer.
